(19) United States
(12) Patent Application Publication
(10) Pub. No.: US 2023/0349992 A1
(43) Pub. Date: Nov. 2, 2023

(54) METHOD AND DEVICE FOR DESIGNING SMOOTH SEQUENCES OF SPOKE ENDPOINTS IN MRI

(71) Applicant: The Regents of the University of California, Oakland, CA (US)

(72) Inventors: Shimon M. Lustig, Oakland, CA (US); Gopal R. Nataraj, Oakland, CA (US)

(21) Appl. No.: 18/304,702

(22) Filed: Apr. 21, 2023

Related U.S. Application Data
(60) Provisional application No. 63/333,622, filed on Apr. 22, 2022.

(51) Int. Cl. G01R 33/48; G01R 33/565

(52) U.S. Cl. CPC G01R 33/4824; G01R 33/56509

(57) ABSTRACT

Systems and methods to design spoke sequences that maximize k-space coverage density while obeying a limit on the angular distance between adjacent spokes. A method includes defining L latitudes on a unit sphere, wherein L is a positive integer, wherein for each 1 ε {0, . . . , L−1}, the lth latitude includes all points on the unit sphere at a geodesic distance (2l+1)π/2L from a pole of the unit sphere, defining a plane that intersects both poles of the unit sphere, and rotating a set of semicircles on one side of the plane about an axis perpendicular to the plane to form at least one closed continuous path on the unit sphere, wherein a rotation angle is given as π(2M+½L) for an integer M. The method also includes periodically sampling along the closed continuous path(s) to yield a sequence of spoke directions.

### CROSS-REFERENCES TO RELATED APPLICATIONS

This patent application claims the benefit of U.S. Provisional Patent Application No. 63/333,622, filed Apr. 22, 2022 and entitled, “Method and Device for Designing Smooth Sequences of Spoke Endpoints in MRI,” which is incorporated by reference in its entirety for all purposes.

### FEDERALLY SPONSORED RESEARCH OR DEVELOPMENT

This invention was made with Government support under contract number HL136965 awarded by the National Institutes of Health. The Government has certain rights in this invention.

### BACKGROUND

Magnetic resonance imaging (MRI) systems acquire data by sampling spatial frequency space (k-space), and dense k-space coverage is required to produce useful images. k-space trajectory design refers to the problem of selecting the sequence of spatial frequencies to sample. One common sampling strategy records k-space measurements along a sequence of spokes, where each spoke is a smooth path that radially emanates from or passes through the origin (i.e., intersects the origin and a point on the unit sphere). Radial MRI acquisitions typically hold the spoke curvature constant and acquire all k-space samples at a given spoke direction before changing directions. Thus, radial k-space trajectory design usually amounts to selecting a sequence of spoke directions. In some applications, it is desirable to space adjacent spokes closely.

A key advantage of radial MRI is that it enables imaging in the presence of motion. Radial trajectories suitable for motion-tolerant imaging must order spoke directions to achieve uniform angular sampling quickly and to maintain consistent angular coverage for the full scan duration. Current motion-tolerant radial sampling strategies realize these characteristics by designing large angles between adjacent spokes. In certain MRI pulse sequences, however, large spoke direction changes can exaggerate image artifacts due to eddy-current effects, introduce unintended contrast changes and artifacts due to incomplete magnetization spoiling, and/or increase acoustic noise. In these situations, it is therefore common to use radial k-space trajectories that space adjacent spokes close to each other, despite reduced motion tolerance.

### SUMMARY

The present disclosure provides systems and methods to design spoke sequences that maximize k-space coverage density while obeying a limit on the angular distance between adjacent spokes. For example, the present disclosure advantageously provides novel systems and methods to design radial trajectories that achieve uniform k-space coverage without large jumps between adjacent spokes. The present embodiments consider radial trajectory design as an optimal path-finding problem on a sphere and extracts suitable spoke sequences from solutions. One embodiment enables quieter imaging without loss in image quality. Other embodiments yield advantages in applications that are sensitive to eddy-currents, partial spoiling, and motion.

According to an embodiment, a computer-implemented method of constructing a sequence of spoke directions for use in radial magnetic resonance imaging (MRI) applications is provided. The method includes defining L latitudes on a unit sphere, wherein L is a positive integer, wherein for each 1 ε {0, . . . , L−1}, the lth latitude includes all points on the unit sphere at a geodesic distance (2l+1)π/2L from a pole of the unit sphere, defining a plane that intersects both poles of the unit sphere, and rotating a set of semicircles on one side of the plane about an axis perpendicular to the plane to form at least one closed continuous path on the unit sphere, wherein a rotation angle is given as π(2M+½L) for an integer M. The method also typically includes periodically sampling along the closed continuous path(s) to yield a sequence of spoke directions. The method may further include imaging a sample based on the sequence of spoke directions.

In certain aspects, the method may further include adjusting the mode number M to control polar and/or azimuthal angular velocity. In certain aspects, M is selected to be about L/2.

In certain aspects, the method may further include adjusting any one or more of (1) the mode number M, (2) the sampling period, or (3) the sample ordering, such that spoke subsequences also maintain uniform spherical coverage.

In certain aspects, differences in sample spacing parallel versus perpendicular to a path are deliberately introduced to provide a field-of-view (FOV)-maximizing trajectory for a given maximum spoke endpoint spacing and trajectory length.

In certain aspects, the method may further include adjusting the mode number M to produce spherical trajectories consisting of multiple interleaving components. In certain aspects, the method further includes adjusting the mode number M to control sampling anisotropy.

According to another embodiment, a computer-implemented method of constructing a sequence of spoke directions for use in radial magnetic resonance imaging (MRI) applications is provided. The method includes defining S semicircles on a unit hemisphere for any odd S, wherein S is a positive integer, wherein for each s ε {0, . . . , S−1} the sth semicircle includes all points on the unit hemisphere at geodesic distance (s+1)π/S+1 from a pole of the unit hemisphere, reflecting every other semicircle about the origin and onto the complementary unit hemisphere, and rotating each of the reflected semicircles about an axis perpendicular to the plane separating the unit hemisphere and the complementary unit hemisphere to form at least one continuous path on the unit sphere. The method also typically includes periodically sampling along the closed continuous path(s) to yield a sequence of spoke directions. The method may further include imaging a sample based on the sequence of spoke directions.

In certain aspects, a rotation angle is expressed as Mπ/S+1 for any odd M such that gcd(S+1, M)≤2.

In certain aspects, the method may further include adjusting the mode number M to control polar and/or azimuthal angular velocity. In certain aspects, M is selected to be about L/2.

In certain aspects, the method may further include adjusting any one or more of (1) the mode number M, (2) the sampling period, or (3) the sample ordering, such that spoke subsequences also maintain uniform spherical coverage.

In certain aspects, differences in sample spacing parallel versus perpendicular to a path are deliberately introduced to provide a field-of-view (FOV)-maximizing trajectory for a given maximum spoke endpoint spacing and trajectory length.

In certain aspects, the method may further include adjusting the mode number M to produce spherical trajectories consisting of multiple interleaving components.

In certain aspects, the method may further include adjusting the mode number M to control sampling anisotropy.

According to yet other embodiments, a non-transitory computer readable medium is provided that stores instructions, which when executed by one or more processors, cause the one or more processors to implement any method of constructing a sequence of spoke directions for use in radial magnetic resonance imaging (MRI) applications as described herein.

Reference to the remaining portions of the specification, including the drawings and claims, will realize other features and advantages of the present invention. Further features and advantages of the present invention, as well as the structure and operation of various embodiments of the present invention, are described in detail below with respect to the accompanying drawings. In the drawings, like reference numbers indicate identical or functionally similar elements.

### BRIEF DESCRIPTION OF DRAWINGS

FIGS. 1A-C outlines a procedure for constructing a sequence of spoke ray directions according to an embodiment.

FIGS. 2A-C adapt the procedure in FIGS. 1A-C to design a sequence of spoke line directions according to an embodiment.

FIGS. 3A-3C compare an embodiment of the present invention to a conventional spherical spiral spoke ordering method in an imaging phantom.

FIGS. 4A and 4B illustrate a comparison similar to FIGS. 3A-3C but in human brain.

FIG. 5A depicts how these golden-ratio trajectories maintain small maximal spherical gaps over short subsequences of the full trajectory.

FIG. 5B provides an example of an alternative type of trajectory.

FIG. 5C provides examples of closed-loop and open-loop discontinuous variations.

FIG. 6 is a block diagram of a processing system according to an embodiment.

### DETAILED DESCRIPTION

The following detailed description is exemplary in nature and is not intended to limit the invention or the application and uses of the invention. Furthermore, there is no intention to be bound by any expressed or implied theory presented in the following detailed description or the appended drawings.

The present disclosure advantageously provides novel systems and methods to design radial trajectories that achieve uniform k-space coverage without large jumps between adjacent spokes. The present embodiments consider radial trajectory design as an optimal path-finding problem on a sphere and extracts suitable spoke sequences from solutions. One demonstrated embodiment enables quieter imaging without loss in image quality. Other embodiments yield advantages in applications that are sensitive to eddy-currents, partial spoiling, and motion.

According to an embodiment, one radial trajectory design approach is to first consider a related path traversal problem and then from its solution extract a suitable sequence of spoke directions. A zero spoke curvature is assumed for ease of exposition (in which case spokes reduce to rays or lines), though the approach can be applied to cases of nonzero curvature as well. To see the relation to path traversal, one can observe that the intersection between a spoke ray and the unit sphere or a spoke line and a unit hemisphere is a single point, and that there is a one-to-one correspondence between a spoke and its intersection point. Thus radial k-space trajectory design is equivalent to designing a path on the unit sphere or hemisphere.

Spoke ray direction design is focused on initially for simplicity. In this case, enforcing small angular variation between adjacent spokes corresponds to limiting path design to smooth curves on a sphere. For uniform k-space coverage, a smooth path on a sphere is sought that avoids leaving large spherical regions untraversed. This objective defines a topological covering problem, and several specific formulations have been examined in abstract contexts outside MRI [1-4]. The present disclosure builds on recent work in geometry [3] to provide novel design techniques and designs.

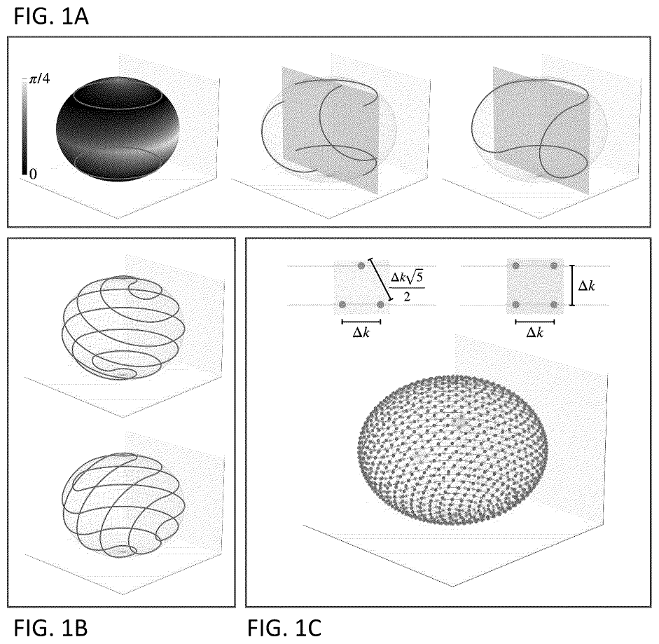

FIGS. 1A-C outlines a procedure for constructing a smoothly-varying sequence of spoke ray directions according to an embodiment. In an initial step, L latitudes are defined on the unit sphere for any positive integer L, where for each 1 ε {0, . . . , L−1} the lth latitude includes all points on the unit sphere at geodesic distance (2l+1)π/2L from a northern pole of the unit sphere. In the example depicted at the left in FIG. 1A, L=2. This set of latitudes avoids large untraversed regions by construction, leaving a maximum geodesic distance π/2L between any point on the unit sphere and the nearest latitude. A bar showing a scale on the left of FIG. 1A shows a maximum geodesic distance of π/4 when L=2. Next, as shown in the center of FIG. 1A, a plane is defined that intersects both poles (northern and southern) and then a set of semicircles on one side of the plane is rotated about an axis perpendicular to this plane. In an embodiment, with the rotation angle being expressed as π(2M+½L) for an integer M such that L, M are relatively prime, a closed continuous path emerges. See FIG. 1B. These paths, or trajectories, can balance polar and azimuthal mean velocities This continuous path shares the same maximum geodesic distance π/2L as the set of latitudes from which it was constructed, and it can be proven that π/2L is in fact the minimum possible max geodesic distance achievable by any spherical path of this length. Several values of M achieve this minimum for L>2 and correspond to different solution modes; specific modes are discussed further below. In an embodiment, periodically sampling along the path with fixed interval π/L yields a sequence of spoke ray directions that balances k-space coverage uniformity in directions parallel versus perpendicular to the path. As seen in FIG. 1C, near-perfect spherical sampling uniformity may be achieved.

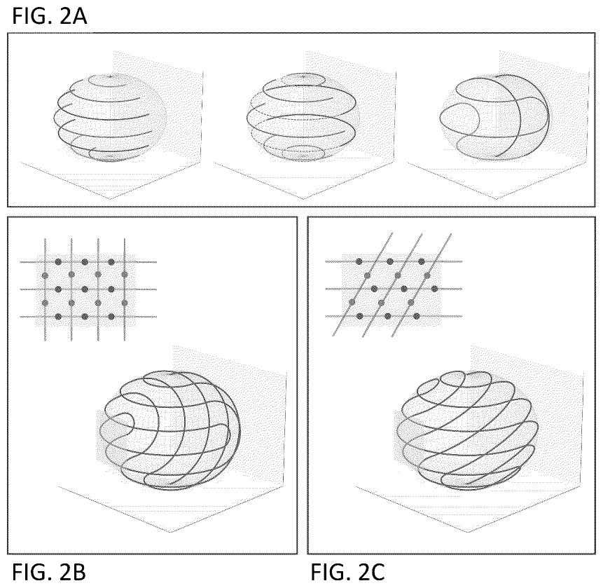

FIGS. 2A-C adapt the above procedure to design a smoothly-varying sequence of spoke line directions according to another embodiment. In an initial step, S evenly spaced semicircles are defined on a unit hemisphere for any odd S, where for each s ε {0, . . . , S−1} the sth semicircle includes all points on the hemisphere at geodesic distance (s+1)π/S+1 from one point on the hemisphere's edge, hereafter defined as the northern pole. An example of the S semicircles and the point defined as the northern pole is shown at the left of FIG. 2A. The set consisting of these S semicircles plus both poles maintains an average geodesic distance π/4S between itself and the set of all points on the associated unit hemisphere. Next, as shown at the center of FIG. 2A, every other semicircle is reflected about the origin and onto the complementary unit hemisphere. Then, as seen at the right of FIG. 2A, the reflected semicircles are rotated about an axis perpendicular to the separating plane. In an embodiment, with the rotation angle being expressed as Mπ/S+1 for any odd M such that gcd(S+1, M)≤2, a continuous path emerges on the unit sphere. This continuous nonintersecting spherical path corresponds to a cross-hatched path on the original unit hemisphere. Periodic sampling yields a sampling pattern that interlaces the cross-hatch points. See, for example, FIG. 2B. However, adjacent semicircles are of different arclengths for S>3, in which case periodic sampling interlaces between cross-hatch points. In an embodiment, the mode number M may be adjusted to enable control of sampling anisotropy: rotation angles close to π/2 for odd n correspond to near-isotropic sampling with average geodesic distance close to π/3S, while other rotation angles correspond to anisotropic sampling (see FIG. 2C) and may be suitable for imaging with anisotropic fields of view.

Zero echo time (ZTE) imaging is a type of radial acquisition that enables imaging short-T₂ species such as bone, myelin, and cancerous lung nodules. Unlike most MRI pulse sequences, ZTE scans can be operated quietly if spoke directions are changed slowly. For quiet and efficient ZTE imaging, it is thus desirable to space adjacent spokes closely. The following results elucidate how the present embodiments can provide advantages for quiet ZTE imaging.

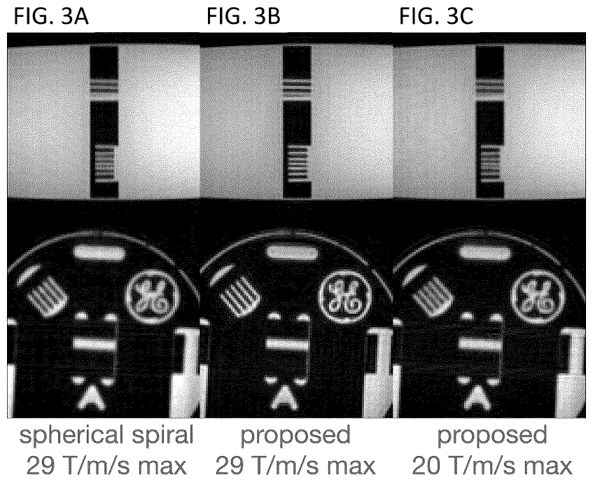

FIGS. 3A-3C compare an embodiment of the present invention (FIGS. 3B and 3C) to a conventional spherical spiral spoke ordering method (FIG. 3A) in an imaging phantom. Each column depicts cross-sectional slices of 3D volumes acquired in equal scan times using different spoke ordering methods. Results show that the proposed approach can achieve higher image resolution for a fixed maximum rate of change in spoke direction (FIG. 3B), or comparable image resolution with ˜30% lower maximum rate of change (FIG. 3C).

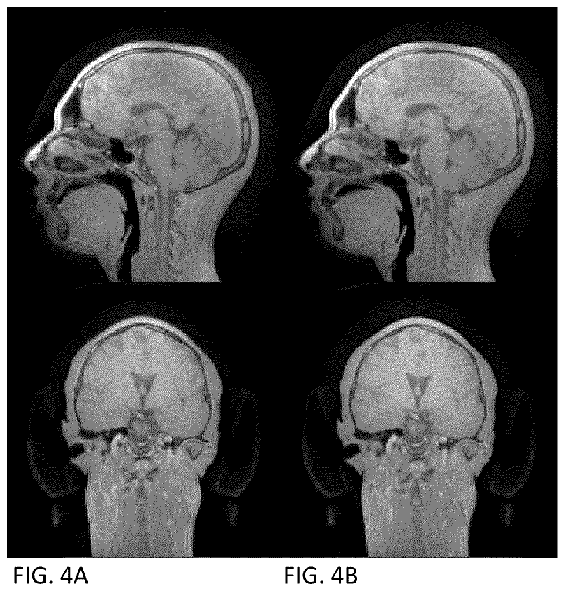

FIGS. 4A and 4B illustrate a comparison similar to FIGS. 3A-3C but in human brain. FIG. 4A shows sagittal (top) and coronal (bottom) views of the brain of a normal volunteer produced using a conventional spherical spiral spoke order. With this conventional approach, the maximum rate of change in spoke direction was 27 Tesla per meter per second (T/m/s). The same views are presented in FIG. 4B, where a current embodiment of the disclosure has a maximum rate of change in spoke direction of 20 T/m/s. Results show that the proposed approach achieves image quality comparable to spherical spiral trajectory design but with ˜30% lower peak rate of change in spoke direction.

### Advantages Compared to Alternatives

Several related works propose radial k-space trajectories that avoid large gaps between adjacent spokes. The Archimedian spherical spiral [5] achieves provably uniform sampling and is simple to implement, but it is not amenable to interleaving [6] and single-interleaf designs are susceptible to motion-induced errors along the polar direction. The spherical spiral phyllotaxis [6, 7] is more amenable to interleaving and has been demonstrated for motion-compensated imaging, but its sample spacing (and thus field of view) depends on the number of interleaves and its sample distribution along the polar direction is suboptimal. A recent method called AZTEK [8] has also been demonstrated for motion-compensated imaging and enables separate control of directional velocities versus the number of interleaves, but its rapid turns at the poles necessitate either substantial variation in gradient slew rates or oversampling near the poles.

The present embodiments enable uniform sampling for any number of interleaves, maximal gradient slew rate efficiency over the full scan duration, and separate control of directional velocities versus the number of interleaves.

### Specific Embodiments & Variations

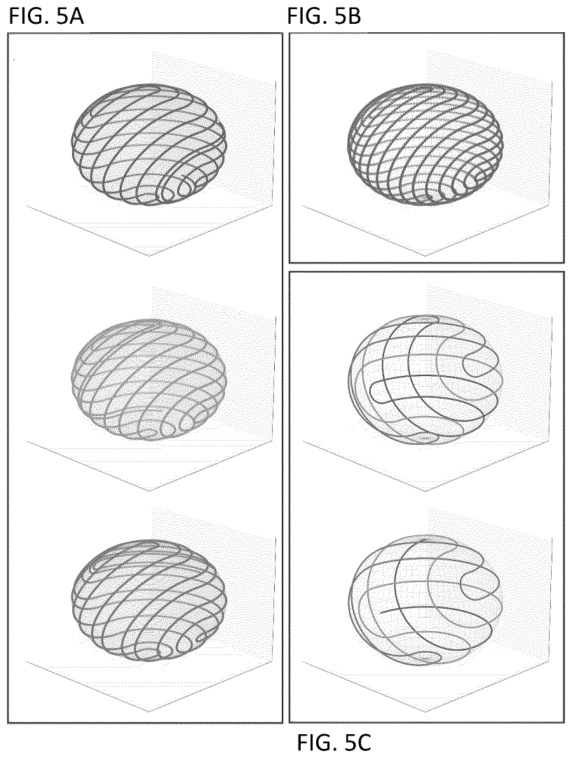

Motion-Tolerant Modes: As stated above, there is flexibility in selecting the rotation mode M during trajectory construction. FIG. 1B illustrates that this flexibility affords control over polar versus azimuthal trajectory mean velocity, which can be useful for motion robustness. To minimize motion sensitivity in a particular direction, one may select a mode with high polar velocity M≈L/2 and orient the polar axis in that direction. For isotropic motion insensitivity, selecting M such that L/M approximates the golden ratio results in a trajectory that balances polar and azimuthal mean velocity. FIG. 5A depicts how these golden-ratio trajectories maintain small maximal spherical gaps over short subsequences of the full trajectory, similar to conventional motion-tolerant radial imaging. At the top of FIG. 5A is a realistic motion-tolerant trajectory (thin gray) consisting of 35,568 spokes (L, M 165, 102). The top of FIG. 5A shows that a reasonable coverage uniformity is achieved within the first 3,000 spokes (dark blue). This coverage uniformity is maintained for equally long subsequences (FIG. 5A middle and bottom) over the full scan duration.

Flexible Constraints: The present disclosure teaches approaches for setting trajectory design constraints. One default mode of operation accepts a target field of view (FOV) and target resolution and designs the shortest trajectory possible given gradient hardware limitations. FIG. 1C depicts an example of this type of trajectory and highlights that this variation roughly balances spoke endpoint spacing perpendicular versus parallel to the trajectory path. For applications with higher sensitivity to spoke jumps and/or lower-performance gradients, an alternate setting is available that designs a FOV-maximizing trajectory for a given maximum spoke endpoint spacing and trajectory length. FIG. 5B provides an example of this alternative type of trajectory and shows how for this mode the spoke endpoint spacing perpendicular to the trajectory path dictates the effective FOV.

Interleaved: Discontinuous trajectories consisting of multiple connected components arise when certain requirements on the trajectory rotation mode M are relaxed. These trajectory variations can arise from either closed-loop or open-loop constructions, and are respectively comprised of gcd(L, M) or gcd(S+1, M)/2+1 components. FIG. 5C provides examples of closed-loop (top) and open-loop (bottom) discontinuous variations and shows that individual components interleave. It can be shown that this interleaving phenomenon is general: for a C-component trajectory, the maximum spherical gap of each interleave is no more than 2C times greater than the overall trajectory's maximum gap. Interleaved trajectories may be suitable for motion compensation, in particular for self-navigation.

FIG. 6 is a block diagram of a processing system according to an embodiment. The processing system 600 can be used to implement the protocols, devices, mechanism, systems and methods described above. The processing system 600 includes one or multiple processors 604, e.g., a central processing unit (CPU) of a computing device or a distributed processor system. The processor(s) 604 execute processor executable instructions for performing the functions and methods described above. In embodiments, the processor executable instructions are locally stored or remotely stored and accessed from a non-transitory computer readable medium, such as storage 610, which may be a hard drive, cloud storage, flash drive, etc. Read Only Memory (ROM) 606 includes processor executable instructions for initializing the processor(s) 604, while the random-access memory (RAM) 608 is the main memory for loading and processing instructions executed by the processor(s) 604. The network interface 612 may connect to a wired network or cellular network and to a local area network or wide area network, such as the Internet, and may be used to receive and/or transmit data, including datasets such as datasets representing one or more images. MRI acquisition device 614 is communicably coupled with the elements of processing system 600 to enable MRI image acquisition according to the optimized spoke sampling paths of the present embodiments.

U.S. Pat. No. 9,778,338 (“Method for Simultaneous Multi-Slice Magnetic Resonance Imaging”), which is incorporated by reference in its entirety, provides additional system features useful with the various embodiments herein. For example, with reference to FIG. 1 of U.S. Pat. No. 9,778,338, the host computer 110 may be useful for designing and prescribing the spoke sequence(s), the gradient system 124 may be useful to execute the spoke sequence(s), and the receiver coil array 134 may be useful to image a sample or acquire imaging data.

### Example Commercial Applications

Zero echo time (ZTE) imaging is a type of radial acquisition where closely-spaced spokes enable quiet operation, of potential interest for pediatric, sleep, and speech imaging. It has been demonstrated that the present embodiments enable quieter or shorter ZTE acquisitions with no loss in image quality.

Balanced steady-state free precession (bSSFP) imaging is used routinely for cardiac imaging, and radial variations are well-suited to compensate for cardiac motion. Motion-tolerant radial bSSFP imaging conventionally requires large gaps between spokes, but larger gaps amplify dark-band artifacts. The present embodiments advantageously reduce banding artifacts in balanced radial imaging without sacrificing on motion tolerance.

In ultrashort echo time (UTE) lung imaging, magnetization spoiling is required to avoid undesired contrast changes due to magnetization refocusing, but spoiling gradients reduce scan efficiency. Closely-spaced spokes also induce spoiling effects, but large gaps between spokes are typically needed for motion robustness. The present embodiments advantageously reduce or eliminate the need for spoiling gradients, thereby improving UTE lung imaging efficiency.

### REFERENCES

[1] E. Saff and A. Kuijlaars, “Distributing many points on a sphere,” Mathematical Intelligencer, vol. 19, no. 1, pp. 5-11, December 1997.

[2] E. Katsav, M. Adda-Bedia, and A. Boudaoud, “A statistical approach to close packing of elastic rods and to DNA packaging in viral capsids,” Proceedings of the National Academy of Sciences, vol. 103, no. 50, pp. 18 900-4,2006.

[3] H. Gerlach and H. von der Mosel, “On sphere-filling ropes,” American Mathematics Monthly, vol. 118, no. 10, pp. 863-76,2011.

[4] C. Yu, H. Schumacher, and K. Crane, “Repulsive curves,” ACM Transactions on Graphics, vol. 40, no. 2, May 2021.

[5] S. T. S. Wong and M. S. Roos, “A strategy for sampling on a sphere applied to 3D selective RF pulse design,” Magnetic Resonance in Medicine, vol. 32, no. 6, pp. 778-84, December 1994.

[6] D. Piccini, A. Littmann, S. Nielles-Vallespin, and M. Zenge, “Spiral phyllotaxis: the natural way to construct a 3D radial trajectory in MM,” Magnetic Resonance in Medicine, vol. 66, no. 4, pp. 1049-56, October 2011.

[7] D. Piccini and M. Zenge, “Method and device for uniform radial data acquisition in threedimensional k-space in an MR measurement for a magnetic resonance system,” U.S. Pat. No. 8,648,594B2, 2014.

[8] T. Boucneau, B. Fernandez, F. Besson, A. Menini, F. Wiesinger, E. Durand, C. Caramella, L. Darrasse, and X. Maitre, “AZTEK: adaptive zero TE k-space trajectories,” Magnetic Resonance in Medicine, vol. 85, no. 2, pp. 926-35, February 2020.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the disclosed subject matter (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or example language (e.g., “such as”) provided herein, is intended merely to better illuminate the disclosed subject matter and does not pose a limitation on the scope of the invention unless otherwise claimed. No language in the specification should be construed as indicating any non-claimed element as essential to the practice of the invention.

Certain embodiments are described herein. Variations of those embodiments may become apparent to those of ordinary skill in the art upon reading the foregoing description. The inventors expect skilled artisans to employ such variations as appropriate, and the inventors intend for the embodiments to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

1. A computer-implemented method of constructing a sequence of spoke directions for use in radial magnetic resonance imaging (MM) applications, the method comprising:
defining L latitudes on a unit sphere, wherein L is a positive integer, wherein for each 1 ε {0, . . . , L−1}, the lth latitude includes all points on the unit sphere at a geodesic distance (2l+1)π/2L from a pole of the unit sphere;
defining a plane that intersects both poles of the unit sphere;
rotating a set of semicircles on one side of the plane about an axis perpendicular to the plane to form at least one closed continuous path on the unit sphere, wherein a rotation angle is given as π(2M+½L) for an integer M; and
periodically sampling along the closed continuous path(s) to yield a sequence of spoke directions.

2. The method of claim 1, further including adjusting the mode number M to control polar and/or azimuthal angular velocity.

3. The method of claim 2, wherein M is selected to be about L/2.

4. The method of claim 1, further including adjusting any one or more of (1) the mode number M, (2) the sampling period, or (3) the sample ordering, such that spoke subsequences also maintain uniform spherical coverage.

5. The method of claim 1, wherein differences in sample spacing parallel versus perpendicular to a path are deliberately introduced to provide a field-of-view (FOV)-maximizing trajectory for a given maximum spoke endpoint spacing and trajectory length.

6. The method of claim 1, further including adjusting the mode number M to produce spherical trajectories consisting of multiple interleaving components.

7. The method of claim 6, further including adjusting the mode number M to control sampling anisotropy.

8. A computer-implemented method of constructing a sequence of spoke directions for use in radial magnetic resonance imaging (MM) applications, the method comprising:
defining S semicircles on a unit hemisphere for any odd S, wherein S is a positive integer, wherein for each s ε {0, . . . , S−1} the sth semicircle includes all points on the unit hemisphere at geodesic distance (s+1)π/S+1 from a pole of the unit hemisphere;
reflecting every other semicircle about the origin and onto the complementary unit hemisphere;
rotating each of the reflected semicircles about an axis perpendicular to the plane separating the unit hemisphere and the complementary unit hemisphere to form at least one continuous path on the unit sphere; and
periodically sampling along the continuous path(s) to yield a sequence of spoke directions.

9. The method of claim 8, wherein a rotation angle is expressed as Mπ/S+1 for any odd M such that gcd(S+1, M)≤2.

10. The method of claim 9, further including adjusting the mode number M to control polar and/or azimuthal angular velocity.

11. The method of claim 10, wherein M is selected to be about L/2.

12. The method of claim 9, further including adjusting any one or more of (1) the mode number M, (2) the sampling period, or (3) the sample ordering, such that spoke subsequences also maintain uniform spherical coverage.

13. The method of claim 8, wherein differences in sample spacing parallel versus perpendicular to a path are deliberately introduced to provide a field-of-view (FOV)-maximizing trajectory for a given maximum spoke endpoint spacing and trajectory length.

14. The method of claim 9, further including adjusting the mode number M to produce spherical trajectories consisting of multiple interleaving components.

15. The method of claim 14, further including adjusting the mode number M to control sampling anisotropy.

16. A non-transitory computer readable medium that stores instructions, which when executed by one or more processors, cause the one or more processors to implement a method of constructing a sequence of spoke directions for use in radial magnetic resonance imaging (MRI) applications, the method comprising:
(A): defining L latitudes on a unit sphere, wherein L is a positive integer, wherein for each 1 ε {0, . . . , L−1}, the lth latitude includes all points on the unit sphere at a geodesic distance (2l+1)π/2L from a pole of the unit sphere;
defining a plane that intersects both poles of the unit sphere; and
rotating a set of semicircles on one side of the plane about an axis perpendicular to the plane to form at least one closed continuous path on the unit sphere, wherein a rotation angle is given as π(2M+½L) for an integer M; and
periodically sampling along the continuous path(s) to yield a sequence of spoke directions,
or
(B): defining S semicircles on a unit hemisphere for any odd S, wherein S is a positive integer, wherein for each s ε {0, . . . , S−1} the sth semicircle includes all points on the unit hemisphere at geodesic distance (s+1)π/S+1 from a pole of the unit hemisphere;
reflecting every other semicircle about the origin and onto the complementary unit hemisphere;
rotating each of the reflected semicircles about an axis perpendicular to the plane separating the unit hemisphere and the complementary unit hemisphere to form at least one continuous path on the unit sphere, wherein a rotation angle is expressed as Mπ/S+1 for any odd M such that gcd(S+1, M)≤2; and
periodically sampling along the continuous path(s) to yield a sequence of spoke directions.

17. The non-transitory computer readable medium of claim 16, wherein the method further includes adjusting the mode number M to control polar and/or azimuthal angular velocity.

18. The non-transitory computer readable medium of claim 17, wherein M is selected to be about L/2.

19. The non-transitory computer readable medium of claim 16, wherein the method further includes adjusting any one or more of (1) the mode number M, (2) the sampling period, or (3) the sample ordering, such that spoke subsequences also maintain uniform spherical coverage.

20. The non-transitory computer readable medium of claim 16, wherein differences in sample spacing parallel versus perpendicular to a path are deliberately introduced to provide a field-of-view (FOV)-maximizing trajectory for a given maximum spoke endpoint spacing and trajectory length.

21. The non-transitory computer readable medium of claim 16, wherein the method further includes adjusting the mode number M to produce spherical trajectories consisting of multiple interleaving components.

22. The non-transitory computer readable medium of claim 21, wherein the method further includes adjusting the mode number M to control sampling anisotropy.
